(19) United States
(12) Patent Application Publication
(10) Pub. No.: US 2014/0264959 A1
(43) Pub. Date: Sep. 18, 2014

(54) HARDENING RESIN COMPOSITION, SEALING MATERIAL, AND ELECTRONIC DEVICE USING THE SEALING MATERIAL

(71) Applicant: DENSO CORPORATION, Kariya-city (JP)

(72) Inventors: Hiroyuki Okuhira, Kariya-city (JP); Akira Takakura, Nagoya-city (JP); Hiroshi Katou, Aichi-gun (JP)

(73) Assignee: DENSO CORPORATION, Kariya-city (JP)

(21) Appl. No.: 14/208,009

(22) Filed: Mar. 13, 2014

(30) Foreign Application Priority Data
Mar. 15, 2013 (JP) 2013-053447

(51) Int. Cl. H01L 23/29

(52) U.S. Cl. CPC H01L 23/293
USPC 257/788; 525/382; 525/351; 525/117

(57) ABSTRACT

A hardening resin composition includes a base resin and a hardening agent. The base resin contains a maleimide compound having two or more maleimide groups in one molecule, and the hardening agent contains a diamine compound expressed by a general chemical formula (1), in which A is an oxygen atom or a sulfur atom, X is a hydrogen atom, an alkyl group with a carbon number of six or less, or an aryl group, and n is a natural number of 1 to 10.

[chemical structure]

### CROSS REFERENCE TO RELATED APPLICATION

This application is based on Japanese Patent Application No. 2013-53447 filed on Mar. 15, 2013, the disclosure of which is incorporated herein by reference.

### TECHNICAL FIELD

The present disclosure relates to a hardening resin composition containing a base resin and a hardening agent, a sealing material made of a hardened material of the hardening resin composition, and an electronic device using the sealing material.

### BACKGROUND

In an electronic device, a sealing material is used so as to protect electronic components, such as a semiconductor element, from an external environment, such as shock, pressure, humidity and heat. As an example of the sealing material, an epoxy, phenol-based sealing material containing an epoxy resin as a base resin and a phenol resin as a hardening agent has been generally used.

In recent years, a semiconductor substrate of electronic devices has been shifted from a Si substrate to a SiC substrate having higher performance. The electronic device having the SiC substrate is assumed to be used in a high temperature environment, such as 200 to 250 degrees Celsius (° C.). On the other hand, the heat-resistant temperature of the epoxy, phenol-based sealing material is from 150 to 200° C. Therefore, development of a sealing material having a higher heat-resistant temperature has been required.

As a material having excellent heat resistance, a heat resistant resin composition that contains a maleimide compound and a polyamine has been developed. (For example, see JP-A-63-68637) Further, a hardened material of the heat resistant resin composition made of such a maleimide-based resin has excellent heat resistance.

### SUMMARY

The hardened material of the heat resistant resin composition made of the maleimide-based resin has excellent heat resistance. However, toughness of the hardened material of the heat resistant maleimide-based resin is insufficient and the hardened material is weak, as compared with the epoxy, phenol-based sealing material, which was conventionally used.

For example, it is possible to improve the toughness of the heat resistant resin composition made of the maleimide compound and the polyamine by adding a softening material, which was used in the epoxy, phenol-based sealing material. In such a case, however, the heat resistance of the heat resistant resin composition is likely to be degraded.

Also, development of new sealing material, which has excellent heat resistance and toughness, for a device, such as a power device used in a high temperature environment, is required.

It is an object of the present disclosure to provide a hardening resin composition, which can provide improved heat resistance and toughness when hardened, a sealing material using the hardening resin composition, and an electronic device using the sealing material.

According to a first aspect of the present disclosure, a hardening resin composition contains a base resin and a hardening agent. The base resin contains a maleimide compound having two or more maleimide groups in a molecule. The hardening agent contains a diamine compound expressed by a general chemical formula (1).

[chemical structure]

In the general chemical formula (1), A is an oxygen atom or a sulfur atom, X is a hydrogen atom, an alkyl group with a carbon number of six or less, or an aryl group, and n is a natural number of 1 to 10.

According to a second aspect of the present disclosure, a sealing material is made of a hardened material of the hardening resin composition according to the first aspect.

According to a third aspect of the present disclosure, an electronic device includes the sealing material according to the second aspect.

The hardening resin composition described above contains the maleimide compound as the base resin and the diamine compound expressed by the general chemical formula (1) as the hardening agent. The hardened material made by hardening the hardening resin composition has excellent heat resistance and toughness. In the hardened material of the hardening resin composition, it is considered that the toughness of the hardened material is improved by the strong interaction between maleimide parts, and the strong stacking hardening due to the hardening agent being aligned on a plane.

The sealing material provided by the hardened material of the hardening resin composition can provide the excellent heat resistance and toughness. Therefore, such a sealing material is, for example, used in an electronic device having a SiC substrate.

When the sealing material described above is used in the electronic device, the sealing material can exert its function even in a high temperature environment, such as over 200 degrees Celsius (° C.). Therefore, the reliability of the electronic device in such a high temperature improves.

### BRIEF DESCRIPTION OF THE DRAWINGS

The above and other objects, features and advantages of the present disclosure will become more apparent from the following detailed description made with reference to the accompanying drawings, in which like parts are designated by like reference numbers and in which:

FIG. 1 is a diagram illustrating a result of data analysis of a thermal-analysis of a hardening agent made of phenylene oxide skeleton diamine (n=3) of an example 1;

FIG. 2 is a diagram illustrating a nuclear-magnetic-resonance (NMR) spectrum of a hardening agent made of phenylene sulfide skeleton diamine (n=3) of an example 2; and

FIG. 3 is a diagram illustrating a schematic cross-sectional view of an electronic device of an example 8.

### DETAILED DESCRIPTION

Exemplary embodiments of the hardening resin composition will be described hereinafter.

In an embodiment, a hardening resin composition contains a maleimide compound as a base resin, and a diamine compound as a hardening agent.

The blending ratio of the base resin and the hardening agent may be suitably determined based on the equivalent ratio of the functional groups of the base resin and the hardening agent so as to have a general relationship between the base resin and the hardening agent. For example, the blending ratio may be determined so that the equivalent ratio of the base resin and the hardening agent is in a range from 0.5 to 1.5, preferably in a range from 0.8 to 1.2, and more preferably in a range from 0.9 to 1.1.

In the hardening resin composition, the ratio of a maleimide equivalent of the base resin and an amine equivalent of the hardening agent may be adjusted in a range from 0.9 to 1.1. In a case where the base resin further contains an epoxy resin, the ratio of the total of the functional group equivalent of the base resin (i.e., total of the maleimide equivalent and the epoxy equivalent) and the equivalent (amine equivalent) of the hardening agent is adjusted, for example, in a range from 0.9 to 1.1, and preferably to 1.

In the hardening resin composition, the base resin includes a maleimide compound that has two or more maleimide groups in a molecule.

The maleimide compound may be a bifunctional-type bismaleimide compound, such as 4,4-diphenylmethanebismaleimide, m-phenylene bismaleimide, bisphenol A diphenyl etherbismaleimide, 3,3-dimethyl-5,5-diphenylmethanebismaleimide, 4-methyl-1,3-phenylene bismaleimide, or 1,6-bismaleimide-(2,2,4-trimethyl) hexane. The maleimide compound may be a multifunctional-type maleimide compound, such as phenylmethanemaleimide. Preferably, the number of the maleimide groups of the maleimide compound is at least 2 and at most 5. Further, a mixture of maleimide compounds each including 2 to 5 maleimide groups may be used. More preferably, the base resin at least includes a bismaleimide compound having two maleimide groups. It is further preferable to use a maleimide compound containing this biamaleimide compound as a main material. In this case, the steric hindrance of the resin structure in the hardened material of the hardening resin composition can be reduced, and toughness can be further improved.

In an embodiment, the hardening resin composition further contains an epoxy resin as the base resin.

In this case, the toughness of the hardened material of the hardening resin composition can be further improved. The toughness of the hardened material is likely to improve with the increase in rate of the epoxy resin in the base resin.

In an embodiment, the hardening resin composition contains a diamine compound expressed by a general chemical formula (1), as the hardening agent.

[chemical structure]

In the general chemical formula (1), A is an oxygen atom or a sulfur atom, X is a hydrogen atom, an alkyl group with a carbon number of 6 or less, or an aryl group, and n is a natural number of 1 to 10.

In the general chemical formula (1), the amino group and the X may be bonded at any positions of a benzene ring. Namely, the amino group and the X may be bonded to the benzene ring at any of an ortho position, a meta position, or a para position.

As the hardening agent, one or more kinds of compounds expressed by the general chemical formula (1) may be used.

In an embodiment, in the general chemical formula (1), benzene skeletons are connected in a meta position or a para position through the A atom.

In this case, the steric hindrance of the resin structure in the hardened material of the hardening resin composition can be reduced, and toughness can be further improved. Preferably, in the general chemical formula (1), the benzene skeletons are all connected in the para position through the A atom.

Further, in the general chemical formula (1), the amino group is preferably connected to the benzene skeleton in the para position with respect to the A atom.

In an embodiment, the X in the general chemical formula (1) is preferably the hydrogen atom or the methyl group. More preferably, the X is the hydrogen atom.

In this case, the steric hindrance of the resin structure in the hardened material of the hardening resin composition can be reduced, and toughness can be further improved.

In the general chemical formula (1), when the natural number n excessively increases, it is difficult to synthesize the diamine compound. In the general chemical formula (1), therefore, the natural number n is preferably in a range from 1 to 10, more preferably in a range from 1 to 5, and further more preferably from 1 to 3.

As the compound expressed by the general chemical formula (1), one selected from compounds each having the natural number of 1 to 10, or mixture of two or more compounds having different natural numbers n among the compounds in which the natural number n is 1 to 10 may be used. In a case where a diamine compound having the natural number n of 3 (n=3) is used, the heat resistance and toughness further improve.

In an embodiment, in the general chemical formula (1), the A is an oxygen atom.

In this case, an adhesion property of the hardening resin composition improves. Therefore, the hardening resin composition can be suitably used for a sealing material.

In a case where the A in the general chemical formula (1) is a sulfur atom, the heat resistance and toughness of the hardening resin composition is likely to further improve.

The hardening resin composition may contain a hardening catalyst so as to promote hardening of the hardening resin composition. As the hardening catalyst, a commercial hardening catalyst, which is used for a hardening reaction of a maleimide resin, may be used. Examples of the hardening catalyst are acid catalysts, amine catalysts, imidazole catalysts, and phosphorous-based catalysts. For example, p-toluenesulfonic acid, methylimidazole, phenylimidazole, triphenyl phosphine, or salts thereof may be used as the hardening catalyst.

The hardening resin composition may contain a filler, such as silica. In this case, the coefficient of linear expansion of the hardening resin composition can be adjusted. In this case, therefore, the hardening resin composition can be suitably used for a sealing material of an electronic device. The optimum content of the filler is different depending on the use of the hardening resin composition. For example, when the hardening resin composition is used for a power device product, the content of the filler is preferably 60 to 95 mass % of the total mass of the composition, more preferably 70 to 90 mass %, and further more preferably 75 to 85 mass %. In particular, the content of the filler can be suitably adjusted so that the hardening resin composition has a desired coefficient of linear expansion.

Hereinafter, an exemplary embodiment of the sealing material and the electronic device will be described.

The sealing material is provided by the hardened material of the hardening resin composition described above. For example, the sealing material is suitably used for an electronic device or the like. For example, the sealing material is suitably used for a power device having a SiC substrate or the like. In such a case, the excellent heat resistance and toughness of the hardened material of the hardening resin composition can be sufficiently exerted. For example, the power device having the SiC substrate or the like is likely to be subjected to a high temperature environment, such as over 240 degrees Celsius (° C.). Therefore, the excellent heat resistance of the hardened material of the hardening resin composition can be utilized.

An example of the electronic device is a semiconductor module (power card) used for a power control unit (PCU) of a vehicle, such as a hybrid vehicle (HV). The hardened material of the hardening resin composition described above may be used as the sealing material for sealing a power device (semiconductor element for controlling electric power) of the semiconductor module.

It is to be noted that the exemplary embodiments of the hardening resin composition described above may be combined in any various ways if there is no problem nor inconsistency.

### EXAMPLES

Hereinafter, examples 1 to 8 of the hardening resin composition and comparative examples 1 and 2 will be described.

### Example 1

In an example 1, a hardening resin composition containing a maleimide compound as a base resin and a specific diamine compound as a hardening agent was produced. Further, characteristics of a hardened material of the hardening resin composition were evaluated.

First, a diamine compound expressed by a following chemical formula (2) was synthesized.

[chemical structure]

In particular, 4,4′-dihydroxydiphenyl ether and p-chloronitrobenzene were mixed to N,N-dimethylacetamide as a reaction solvent at an equivalent ratio of OH:Cl=1:1.1. Then, the reaction solvent was heated to 80° C. Thereafter, potassium carbonate was added to the reaction solvent so that the equivalent ratio of the hydroxyl group of 4,4′-dihydroxydiphenyl ether and the potassium carbonate is OH:Potassium carbonate=1:1.1.

Next, the reaction solvent was heated at 125° C. for 5 hours to carry out a reaction. Thereafter, the reaction solution was placed into an ion exchange water to carry out redeposition, and a solid material was obtained by filtering the reaction solution. Further, the solid material obtained was washed by heat methanol, and a solid material was obtained by filtration. The solid material obtained was dried. As a result, phenylene ether oligomer (n=3) which has a nitro group at both the ends was obtained. The yield of the phenylene ether oligomer was 90%.

Next, a mixed solvent of isopropyl alcohol and tetrahydrofuran was produced as a reaction solvent. Then, the phenylene ether oligomer having the nitro group at both the ends, which was obtained as described above, and palladium carbon were added to this reaction solvent. The blending ratio (mass ratio) of the phenylene ether oligomer and the palladium carbon was 1:0.05 (phenylene-ether oligomer:palladium carbon).

Next, the reaction solvent was heated to 55° C. Thereafter, hydrated hydrazine was added to the reaction solvent while taking 1 hour. The additive amount of the hydrated hydrazine was adjusted so that the equivalent ratio of the nitro group of the phenylene ether oligomer and the hydrated hydrazine is 1:4 (nitro group:hydrated hydrazine). Next, this reaction solvent was reacted at 60° C. for 5 hours to reduce the nitro group at the ends of the phenylene ether oligomer into an amino group. Thereafter, the palladium carbon was removed from the reaction solvent by hot filtration, and, relative to the preparation amount, ⅔ (volume) of the solvent was distilled off by vacuum concentration. Thereafter, isopropyl alcohol at the same amount (volume) as the distilled solvent was added to the solvent and the solvent was heated to 80° C. Thereafter, the mixture was cooled to deposit a solid material.

Thereafter, the solid material was obtained by filtering, and was then dried. As a result, the phenylene ether oligomer (n=3) having the amino group at both the ends was obtained, as the diamine compound (hardening agent A, phenylene oxide skeleton diamine) expressed by the chemical formula (2). The yield of the phenylene ether oligomer was 85%.

A differential scanning calorimetric analysis (DSC) was conducted for the diamine compound obtained, for example, using a differential scanning calorimeter (e.g., EXSTAR 6000 made by SII Nano Technology Inc). As a result, a sharp peak representing a melting point of an object material was found at a temperature of approximately 126° C. This result is shown in FIG. 1. FIG. 1 illustrates a relationship between a DSC curve and time, and a relationship between the temperature and the time. In FIG. 1, a left-side vertical axis represents a heat flow (mW), a horizontal axis represents the time (minute), and a right-side vertical axis represents a temperature (° C.). The measurement conditions of DSC measurement are also shown in FIG. 1.

Although not illustrated, the structure of the diamine compound obtained was checked by a nuclear-magnetic-resonance (NMR) measurement, and the purity of the diamine compound obtained was checked by a high performance liquid chromatography (HPLC).

Next, a hardening resin composition was prepared using the diamine compound (hardening agent A) produced as described above as the hardening agent. The diamine compound (hardening agent A) is expressed by the chemical formula (2).

As the maleimide compound, phenyl methane type bismaleimide (PMBM) (e.g., BMI-2300 made by DAIWA CHEMICAL INDUCTRY CO., LTD.) was prepared. As a hardening catalyst, triphenyl phosphine salt (TPP salt) (e.g., JPB659 made by JOHOKU CHEMICAL CO., LTD.) was prepared. As a filler, a spherical silica (e.g., RD-8 made by Tatsumori Ltd.) was prepared.

The maleimide compound, the diamine compound, the hardening catalyst and the filler, which were prepared as described above, were put in an open roll (e.g., made by TOYO SEIKI CO., LTD.) heated at the temperature of 110° C. at the blending ratio shown in table 1, and kneaded for 5 minutes. As a result, the hardening resin composition was obtained.

Next, the hardened material of the hardening resin composition obtained was produced, and the heat resistance and the toughness of the hardened material were evaluated.

In particular, the hardening resin composition was molded by transfer molding (mold temperature: 200° C., and for 5 minutes), and hardened. Thus, the hardened material (molded product) was obtained. In the example 1, a cube-shaped TMA specimen (5 mm×5 mm×5 mm) was produced by processing the molded product, as the hardened material for evaluation of the heat resistance. Also, a plate-shaped specimen for a bending test (10 mm width×80 mm length×4 mm thickness) was produced by processing the molded product, as the hardened material for evaluation of the toughness.

The heat resistance was evaluated by measuring a glass transition temperature Tg of the TMA specimen.

The glass transition temperature Tg was measured in a process in which the temperature was lowered from 320° C. to a room temperature (25° C.) at a temperature reduction rate of 5° C./min using a thermomechanical analysis (TMA) device (e.g., EXSTAR6000 made by SII Nano Technology Inc). The measurement result is shown in the table 1. In the evaluation of the heat resistance, “+2” represents a result where the glass transition temperature is 250° C. or more, “+1” represents a result where the glass transition temperature is 240° C. or more and less than 250° C., and “−1” represents a result where the glass transition temperature is less than 240° C.

The toughness was evaluated by measuring a bending distortion of the specimen for the bending test.

The bending distortion was measured by a three-point bending test based on JIS K 7171 (2008). The measurement of the bending distortion was performed under the following conditions.

Distance between supporting points: 64 mm,

Test rate: 2 mm/min,

Measurement temperature: Room temperature (25° C.)

The bending distortion is calculated based on the following equation:

Bending distortion (%)=the amount of bending×6×thickness/(distance between supporting points)²

The measurement result of the bending test is shown in the table 1. In the evaluation of the toughness, “+2” represents a result where the bending distortion is 0.7% or more, “+1” represents a result where the bending distortion is 0.4% or more and less than 0.7%, and “−1” represents a result where the bending distortion is less than 0.4%.

### Examples 2 to 7 and Comparative examples 1 and 2

As examples 2 to 7 and comparative examples 1 and 2, hardening resin compositions were prepared by modifying kinds and/or blending ratios of a base resin, a hardening agent, a hardening catalyst, and/or a filler from the example 1.

In the preparation of the hardening resin compositions of the examples 2 to 7 and the comparative examples 1 and 2, five kinds of hardening agent (hardening agents B to F) are used in addition to the hardening agent A made of the diamine compound expressed by the chemical formula (2) of the example 1. Firstly, the hardening agents B to F will be described.

The hardening agent B is a diamine compound expressed by the following chemical formula (3).

[chemical structure]

The diamine compound (hardening agent B) expressed by the chemical formula (3) was synthesized in the following manner.

Dithio phenylene sulfide and p-chloronitrobenzene were mixed to N,N-dimethylacetamide as a reaction solvent at the equivalent ratio of SH group and Cl group is 1:1.1 (SH:Cl). Thereafter, the reaction solvent was heated to 60° C., and potassium carbonate was added to the reaction solvent so that the equivalent ratio of HS group of the dithio phenylene sulfide and the potassium carbonate is 1:1.1 (SH:potassium carbonate).

Thereafter, the reaction solvent was heated at 120° C. for 5 hours to carry out reaction. Thereafter, the reaction solvent was placed into an ion exchange water to carry out redeposition, and filtered to obtain a solid material. The solid material was washed with heat ethanol, and then was dried. As a result, phenylene sulfide oligomer (n=3) having a nitro group at both the ends was obtained. The yield of the phenylene sulfide oligomer was 80%.

Next, the phenylene sulfide oligomer having the nitro group at both the ends, which was obtained as described above, and palladium carbon were added to isopropyl alcohol as a reaction solvent. The blending ratio (mass ratio) of the phenylene sulfide oligomer and the palladium carbon was 1:0.05 (phenylene sulfide oligomer:palladium carbon).

Thereafter, the reaction solvent was heated to 70° C., and then hydrated hydrazine was added to the reaction solvent while taking 1 hour. The additive amount of the hydrated hydrazine was adjusted so that the equivalent ratio of the nitro group of the phenylene sulfide oligomer and the hydrated hydrazine was 1:4 (nitro group:hydrated hydrazine). Thereafter, the reaction solvent was heated at 80° C. for 5 hours to carry out reaction. As a result, the nitro group at the ends of the phenylene sulfide oligomer was reduced into an amino group. Thereafter, the palladium carbon was removed from the reaction solvent by heat filtration, and then the reaction solvent was cooled to deposit a solid material.

Thereafter, the solid material was obtained by filtration and then dried. As a result, the phenylene sulfide oligomer (n=3) having the amino group at both the ends, that is, the diamine compound expressed by the chemical formula (3) was obtained as the hardening agent B (phenylene sulfide skeleton diamine). The yield of the phenylene sulfide oligomer was 75%.

Further, the structure of the diamine compound obtained was checked by the nuclear-magnetic-resonance (NMR) measurement. The NMR spectrum of the phenylene sulfide oligomer (n=3) expressed by the chemical formula (3) is shown in FIG. 2 for a reference.

The hardening agent C is a diamine compound expressed by the following chemical formula (4) (e.g., phenylene oxide skeleton diamine). As the hardening agent C, TPE-R made by Wakayama Seika Kogyo Co., Ltd. was used.

[chemical structure]

The hardening agent D is a diamine compound expressed by the following chemical formula (5) (e.g., phenylene sulfide skeleton diamine amine). As the hardening agent D, ASD made by Wakayama Seika Kogyo Co., Ltd. was used.

[chemical structure]

The hardening agent E is diaminodiphenyl sulfone (DDS). As the hardening agent E, Aradur 9664-1 made by Huntsman Corporation was used.

The hardening agent F is phenol. As the hardening agent F, TD-2131 made by DIC Corporation was used.

In the examples 5 to 7, as the base resin, an epoxy resin was used in addition to the maleimide compound. As the epoxy resin, HP-4710, which is naphthalene type epoxy resin (NER), made by DIC Corporation was used.

In the examples 2 to 7 and the comparative examples 1 and 2, the maleimide compound (base resin), the hardening catalyst and the filler, which are similar to those of the example 1, were used.

The base resin, the hardening agent, the hardening catalyst and the filler were blended at the blending ratio shown in the table 1, and kneaded in the similar manner to the example 1. As a result, the hardening resin compositions of the examples 2 to 7 and the comparative examples 1 and 2 were produced.

In the similar manner to the example 1, the hardening resin composition of each of the examples 2 to 7 and each of the comparative examples 1 and 2 was hardened to produce a hardened material (molded product), and the heat resistance and the toughness of each hardened material were measured.

The evaluation results are shown in the table 1.

TABLE 1

| | | | | | | | | | | Comp | Comp |
|---|---|---|---|---|---|---|---|---|---|---|---|
| | | | Ex 1 | Ex 2 | Ex 3 | Ex 4 | Ex 5 | Ex 6 | Ex 7 | Ext 1 | Ex 2 |
| Base | Maleimide | FMBM | 100 | 100 | 100 | 100 | 50 | 50 | 10 | 100 | 100 |
| Resin | Comp. | (maleimide | | | | | | | | | |
| (pts.mass) | | eqv.179) | | | | | | | | | |
| | Epoxy | NER | — | — | — | — | 50 | 50 | 90 | — | — |
| | resin | (epoxy eqv.140) | | | | | | | | | |
| Hardening | Diamine | A, n = 3 | 53.6 | — | 26.8 | 26.8 | 61.1 | — | — | — | — |
| Agent | compound | (amine eqv. 96) | | | | | | | | | |
| (pts.mass) | | B, n = 3 | — | 60.3 | — | — | — | 68.7 | 75.5 | — | — |
| | | (amine eqv.108) | | | | | | | | | |
| | | C, n = 2 | — | — | 20.3 | — | — | — | — | — | — |
| | | (amine eqv.73) | | | | | | | | | |
| | | D, n = 1 | — | — | — | 15 | — | — | — | — | — |
| | | (amine eqv. 54) | | | | | | | | | |
| | Amine | E (amine eqv.62) | — | — | — | — | — | — | — | 34.6 | — |
| | Phenols | F (OH eqv.104) | — | — | — | — | — | — | — | — | 58.1 |

| | | | | | | | | | | |
|---|---|---|---|---|---|---|---|---|---|---|
| Hardening catalyst | TPP salt | 1 | 1 | 1 | 1 | 0.5 | 0.5 | 0.2 | 1 | 1 |
| (pts.mass) | | | | | | | | | | |
| Filler | Spherical silica | 618.5 | 645.3 | 592.4 | 571.2 | 646.4 | 677 | 702.6 | 542.5 | 636.4 |
| (pts.mass) | | | | | | | | | | |
| Heat resistance | Tg (° C.) | 246 | 250 | 253 | 265 | 248 | 250 | 254 | 263 | 203 |
| | Determ. | +1 | +2 | +2 | +2 | +1 | +2 | +2 | +2 | −1 |
| Toughness | Bend. dist. (%) | 0.52 | 0.55 | 0.51 | 0.5 | 0.72 | 0.75 | 0.85 | 0.32 | 0.5 |
| | Determ. | +1 | +1 | +1 | +1 | +2 | +2 | +2 | −1 | +1 |

As shown in the table 1, it is appreciated that the hardened material having excellent heat resistance and excellent toughness can be obtained by the hardening resin composition that contains the maleimide compound as the base resin and the diamine compound expressed by the chemical formula (2) to (5) as the hardening agent, that is, the diamine compound expressed by the general formula (1).

### Example 8

Next, an example of an electronic device (electronic device product) will be described, as an example 8. In the electronic device, the hardened material of the hardening resin composition of the example 1 is used as a sealing material.

As shown in FIG. 3, an electronic device 1 of the example 8 is a semiconductor module (power card) used in a power control unit for a hybrid vehicle. The electronic device 1 has an electronic component 10. The electronic component 10 is constructed of a power device 101, a copper spacer 102, and heat radiation copper plates 103, 104, which are soldered to each other by a reflowing technique. The electronic component 10 is sealed in a sealing material 11 together with electrode terminals 105, 106. In FIG. 3, a portion 108 in between the power device 101 and the copper spacer 102, and a portion 109 in between the power device 101 and the heat radiation copper plate 104 are bonding portions 108, 109 made of a solder.

In manufacturing of the electronic device 1, a primer was applied to the electronic component 10 and then the electronic component 10 was placed in a die. Next, the hardening resin composition of the example 1 was injected into the die at the temperature of 200° C., and molded by a transfer molding. Thereafter, the hardening resin composition was held at 250° C. for 4 hours to be hardened. In this way, the electronic device 1 that uses the hardened material of the hardening resin composition of the example 1 as the sealing material 11 was produced.

In the electronic device produce 1 of this example, the hardened material of the hardening resin composition of the example 1, which has the excellent heat resistance and toughness (see the table 1), is used as the sealing material 11. Therefore, even when the electronic device 1 is subjected to a high temperature environment, such as approximately 240° C., the sealing material can sufficiently exert its function and exert excellent toughness. Accordingly, reliability of the electronic device 1 at a high temperature improves.

### Example 9

In the example 8 described above, the electronic device 1 employs the hardened material of the hardening resin composition (phenylene oxide skeleton diamine) of the example 1, as the sealing material. In the example 9, an electronic device (electronic device product) is manufactured using the hardened material of the hardening resin composition (phenylene sulfide skeleton diamine) produced in the example 2 as the sealing material.

The electronic device of the example 9 (semiconductor module) has the similar structure to the electronic device 1 of the example 8, as shown in FIG. 3, except that the electronic device of the example 9 uses the hardening resin composition of the example 2. The hardening resin composition of the example 2 has the excellent heat resistance and toughness (see the table 1). Therefore, even when the electronic device of the example 9 is subjected to a high temperature environment, such as approximately 240° C., the sealing member can sufficiently exert its function and exert excellent toughness. Accordingly, also in the electronic device of the example 9, the reliability at a high temperature improves.

### Comparative Example 3

As a comparative example 3, an electronic device (electronic device product) is manufactured using the hardened material of the hardening resin composition of the comparative example 1 as the sealing material.

The electronic device of the comparative example 3 (semiconductor module) has the similar structure to the electronic device of the example 8 (see FIG. 3), except that the electronic device of the comparative example 3 uses the hardening resin composition of the comparative example 1. The hardening resin composition of the comparative example 1 has the excellent heat resistance. However, the toughness of the hardening resin composition of the comparative example 1 is low (see FIG. 1). Therefore, the reliability of the electronic device of the comparative example 3 is insufficient.

(Comparison of the Example 8, the Example 9 and the Comparative Example 3)

A heating and cooling cycle test was performed for the electronic devices of the example 8, the example 9 and the comparative example 9, and an adhesion property of the sealing material of each example was evaluated.

In particular, a heating and cooling cycle was repeatedly performed 500 times for each of the electronic devices. In one heating and cooling cycle, the electronic device was heated to 250° C., kept at 250° C. for 30 minutes, cooled to −40° C., and kept at −40° C. for 30 minutes. The heating and cooling cycle test was performed using ETAC NT-W (water cooling-type) Series made by Kusumoto Chemicals, Ltd. In each of the electronic devices, separation between the electronic component and the sealing material was checked by sight at 50th cycle, 100th cycle, 250th cycle and 500th cycle. The adhesion property was evaluated at four levels, such as “−1”, “0”, “+1” and “+2”, in which “−1” represents a result where the separation was observed first time at 50th cycle, “0” represents a result where the separation was observed first time at 100th cycle, “+1” represents a result where the separation was observed first time at 250th cycle, and “+2” represents a result where the separation was observed first time at 500th cycle. In the evaluation, there is no electronic device that causes the separation also at the 500th cycle. The results are shown in a table 2.

TABLE 2

| | Ex 8 | Ex 9 | Comp Ex 3 |
|---|---|---|---|
| Hardening resin | Ex 1 | Ex 2 | Comp Ex 1 |
| composition | | | |
| Hardening agent | A | B | E |
| Adhesion property | +2 | +1 | −1 |

In the electronic device of the example 8, the sealing material is provided by the hardening resin composition of the example 1 that uses the phenylene oxide skeleton diamine (hardening agent A) as the hardening agent. In the electronic device of the example 9, the sealing material is provided by the hardening resin composition of the example 2 that uses the phenylene sulfide skeleton diamine (hardening agent B) as the hardening agent. In the electronic device of the comparative example 3, the sealing material is provided by the hardening resin composition of the comparative example 1 that uses the DDS (hardening agent E) as the hardening agent. As shown in the table 2, in the electronic device of the example 8 and the electronic device of the example 9, the sealing materials have the excellent adhesion property. On the other hand, in the electronic device of the comparative example 3, the adhesive property of the sealing member is insufficient. Further, when the example 8 and the example 9 are compared, the adhesive property of the sealing member further improves by using the hardening resin composition of the example 1 in which the phenylene oxide skeleton diamine is used as the hardening agent than the hardening resin composition of the example 2 in which the phenylene sulfide skeleton diamine is used as the hardening agent. Namely, it is appreciated that the A of the general chemical formula (1) described above is preferably an oxygen atom, from a standpoint of the adhesive property of the sealing member.

In the example 8 and the example 9, the hardening resin compositions of the example 1 and the examples 2 are used, respectively. In addition, the electronic device with improved reliability can be also implemented by using the hardening resin compositions of the examples 3 to 7 each having the excellent heat resistance and toughness (see the Table 1).

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. A hardening resin composition comprising:
a base resin; and
a hardening agent, wherein
the base resin contains a maleimide compound having two or more maleimide groups in one molecule, and
the hardening agent contains a diamine compound expressed by a following general chemical formula (1): [chemical structure]
wherein
A is an oxygen atom or a sulfur atom,
X is a hydrogen atom, an alkyl group with a carbon number of six or less, or an aryl group, and
n is a natural number of 1 to 10.

2. The hardening resin composition according to claim 1, wherein
in the general chemical formula (1), benzene skeletons are connected in a meta position or a para position through the atom A.

3. The hardening resin composition according to claim 1, wherein
in the general chemical formula (1), the X is the hydrogen atom.

4. The hardening resin composition according to claim 1, wherein
in the general chemical formula (1), the A is the oxygen atom.

5. The hardening resin composition according to claim 1, wherein
the base resin further contains an epoxy resin.

6. A sealing material provided by a hardened material of the hardening resin composition according to claim 1.

7. An electronic device comprising:
an electronic component; and
a sealing member sealing the electronic component, the sealing member being provided by the sealing material according to claim 6.
